(19) United States
(12) Patent Application Publication
(10) Pub. No.: US 2026/0173421 A1
(43) Pub. Date: Jun. 18, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Kuan-Wun LIN, Hsinchu (TW); Hsien-Chih HUANG, Hsinchu (TW); Guan-Lin CHEN, Hsinchu (TW); Kuo-Cheng CHIANG, Hsinchu (TW); Chih-Hao WANG, Hsinchu (TW)

(73) Assignee: Taiwan Semiconductor Manufacturing Company, Ltd., Hsinchu (TW)

(21) Appl. No.: 18/980,638

(22) Filed: Dec. 13, 2024

(51) Int. Cl. H10D 30/01; H10D 30/00; H10D 30/43; H10D 30/67; H10D 62/10; H10D 64/01; H10D 84/01; H10D 84/83

(52) U.S. Cl. CPC H10D 30/0191; H10D 30/014; H10D 30/43; H10D 30/502; H10D 30/6735; H10D 30/6757; H10D 62/121; H10D 64/015; H10D 64/017; H10D 64/018; H10D 84/0128; H10D 84/0147; H10D 84/0153; H10D 84/832

(57) ABSTRACT

A method for manufacturing a semiconductor device is provided with the following steps. A plurality of first semiconductor layers and a plurality of second semiconductor layers alternately stacked on a substrate are formed. Edge portions of the second semiconductor layers are removed to form a plurality of semiconductor nanosheets between the first semiconductor layers. A plurality of semipermeable films is formed on sidewalls of the semiconductor nanosheets. The semiconductor nanosheets is removed to form a plurality of cavities between the first semiconductor layers. A plurality of sacrificial dielectric layers is deposited in the cavities defined by the semipermeable films.

### BACKGROUND

The electronics industry has a growing demand for smaller and faster electronic devices that can simultaneously support a greater number of increasingly complex functions. Accordingly, there is a continuing trend in the semiconductor industry to manufacture low cost, high performance and low power integrated circuits (ICs). So far, these goals have been achieved largely by reducing IC dimensions (e.g., minimum feature size) of a semiconductor to increase production efficiency and reduce associated manufacture costs. However, this technique of reducing the IC dimensions of the semiconductor also increases the complexity of the semiconductor manufacturing process. Therefore, in order to cope with the continuous improvement and IC technologies of semiconductor, the semiconductor manufacturing processes and related technologies also need to be improved. For example, epitaxial defects and random voids are generated due to growth from noncontinuous silicon surface, and suboptimal isolation is occurred between source/drain epitaxy and the substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of nano-FETs in a three-dimensional view in accordance with some embodiments of the disclosure.

FIGS. 2 to 10 respectively illustrate B-B′ cross-sectional schematic diagrams at various stages of manufacturing a semiconductor device according to embodiments of the present disclosure.

FIGS. 11 to 16 respectively illustrate B-B′ cross-sectional schematic diagrams at various stages for replacing semiconductor nanosheets with dummy dielectric layers according to embodiments of the present disclosure.

FIGS. 17A to 17C respectively illustrate B-B′ cross-sectional schematic diagrams at various stages of replacing dummy inner spacers with dielectric inner spacers according to the first embodiment of the present disclosure.

FIGS. 18A to 18F respectively illustrate B-B′ cross-sectional schematic diagrams at various stages for replacing dummy inner spacers with dielectric hollow inner spacers according to the second embodiment of the present disclosure.

FIGS. 19A to 19C respectively illustrate B-B′ cross-sectional schematic diagrams at various stages for replacing dummy inner spacers with full air inner spacers according to the third embodiment of the present disclosure.

FIGS. 20 to 22 respectively illustrate B-B′ cross-sectional schematic diagrams of semiconductor devices according to embodiments of the present disclosure.

FIGS. 23 to 25 respectively illustrate B-B′ cross-sectional schematic diagrams of semiconductor devices according to other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The embodiments of this disclosure are discussed with respect to nanostructure FETs (e.g., Horizontal Gate All Around (HGAA) FETs, Vertical Gate All Around (VGAA) FETs, nanosheet/nanowire FET, nano-ribbon FET, Multi-Bridge-Channel FET), implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure.

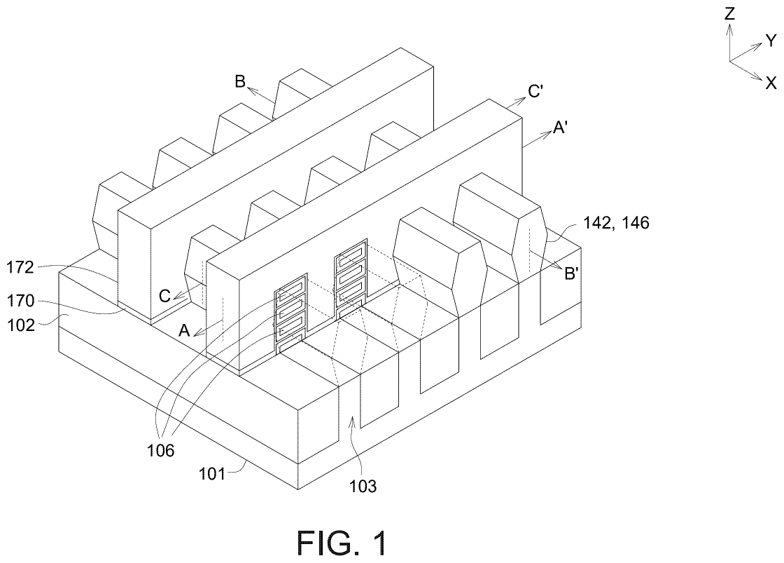

FIG. 1 illustrates an example of nano-FETs (e.g., nanowire FETs, nanosheet FETs, nanostructure FETs, or the like) in a three-dimensional view, in accordance with some embodiments. The nano-FETs comprise nanostructures 106 (e.g., nanosheets, nanowire, or the like) over fins 103 on a substrate 101 (e.g., a semiconductor substrate), wherein the nanostructures 106 act as channel regions for the nano-FETs. The nanostructure 106 may include p-type nanostructures, n-type nanostructures, or a combination thereof. Isolation regions 102 are disposed between adjacent fins 103, which may protrude above and from between neighboring isolation regions 103. Although the isolation regions 102 are described/illustrated as being separate from the substrate 101, as used herein, the term “substrate” may refer to the semiconductor substrate alone or a combination of the semiconductor substrate and the isolation regions. Additionally, although a bottom portion of the fins 103 are illustrated as being single, continuous materials with the substrate 101, the bottom portion of the fins 103 and/or the substrate 101 may comprise a single material or a plurality of materials. In this context, the fins 103 refer to the portion extending between the neighboring isolation regions 102.

Gate dielectric layers 170 are disposed over top surfaces of the fins 103 and along top surfaces, sidewalls, and bottom surfaces of the nanostructures 106. Gate electrode layers 172 are over the gate dielectric layers 170. Epitaxial source/drain features 142 and 146 are disposed on the fins 103 on opposing sides of each of the gate dielectric layers 170 and the gate electrode layers 172.

FIG. 1 further illustrates reference cross-sections that are used in later figures of the semiconductor device 100. Cross-section A-A′ is along a longitudinal axis of a gate electrode layer 102 and in a direction, for example, perpendicular to the direction of current flow between the epitaxial source/drain features 142 and 146 of a nano-FET. Cross-section B-B′ is perpendicular to cross-section A-A′ and is parallel to a longitudinal axis of a fin 103 of the nano-FET and in a direction of, for example, a current flow between the epitaxial source/drain features 142 and 146 of the nano-FET. Cross-section C-C′ is parallel to cross-section A-A′ and extends through the epitaxial source/drain features 142 and 146 of the nano-FETs. Subsequent figures refer to these reference cross-sections for clarity.

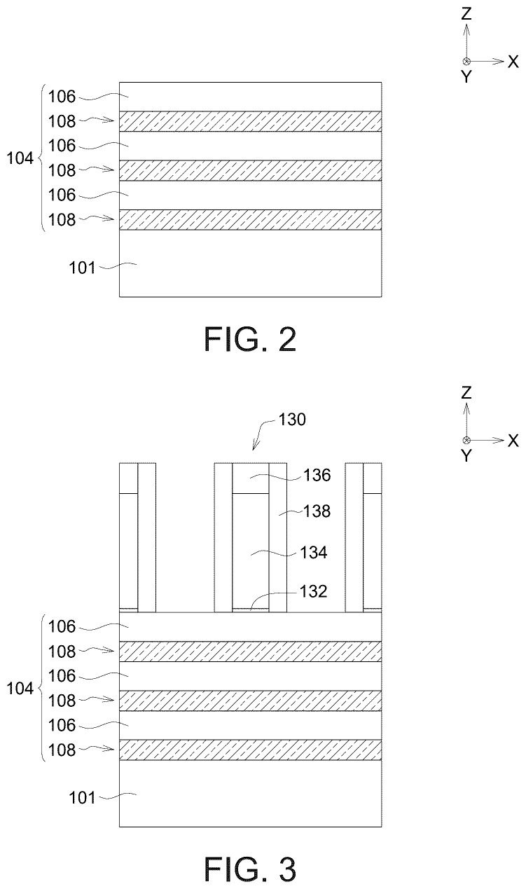

FIGS. 2 to 10 illustrate B-B′ cross-sectional schematic diagrams at various stages of manufacturing the semiconductor device 100 according to embodiments of the present disclosure. It would be appreciated that for additional embodiments of the method, additional steps may be provided before, during, and after the processes illustrated in FIGS. 2 to 10, and some of the steps described below may be replaced or eliminated. The sequence of steps/processes is not limited and interchangeable.

As shown in FIG. 2, a semiconductor device includes a stack of semiconductor layers 104 formed over a substrate 101. The substrate 101 may be a semiconductor substrate. The substrate 101 may include single crystal semiconductor materials such as, but not limited to, silicon (Si), germanium (Ge), silicon germanium (SiGe), gallium arsenide (GaAs), indium antimonide (InSb), gallium phosphide (GaP), Gallium antimonide (GaSb), indium aluminum arsenide (InAlAs), indium gallium arsenide (InGaAs), gallium antimony phosphide (GaSbP), gallium arsenide antimonide (GaAsSb) and indium phosphide (InP). In some embodiments, the substrate 101 is a silicon-on-insulator (SOI) substrate having an insulating layer (not shown) disposed between two silicon layers for reinforcement. In one aspect, the insulating layer is an oxygen-containing layer.

The substrate 101 may include various regions that have been doped with impurities (e.g., dopants having p-type or n-type conductivity). Depending on circuit design, the dopants may be, for example boron for p-type field effect transistors (PFET) and phosphorus for n-type field effect transistors (NFET).

The stack of semiconductor layers 104 includes semiconductor layers made of different materials to facilitate the formation of nanostructure channels in a multi-gate device, such as nanostructure FETs. In some embodiments, the stack of semiconductor layers 104 includes first semiconductor layers 106 (i.e., nanostructures in FIG. 1) and second semiconductor layers 108. In some embodiments, the stack of semiconductor layers 104 includes alternating first semiconductor layers 106 and second semiconductor layers 108, and the first semiconductor layers 106 and the second semiconductor layers 108 are disposed parallel to each other. The first semiconductor layers 106 and the second semiconductor layers 108 are made of semiconductor materials with different etching selectivities and/or different oxidation rates. For example, the first semiconductor layers 106 can be made of Si, and the second semiconductor layers 108 can be made of SiGe. In some examples, the first semiconductor layers 106 may be made of silicon doped with Ge, and second semiconductor layers 108 may be made of SiGe. In some examples, the first semiconductor layers 106 can be made of SiGe and the second semiconductor layers 108 can be made of Si. In some embodiments, the first semiconductor layers 106 can be made of SiGe having a first germanium concentration range, and the second semiconductor layers 108 can be made of SiGe having a second germanium concentration range that is lower or greater than the first germanium concentration range. Alternatively, in some embodiments, any one of the first semiconductor layers 106 and the second semiconductor layers 108 may be or include other materials, such as Ge, SiC, GeAs, GaP, InP, InAs, InSb, GaAsP, AlInAs, AlGaAs, InGaAs, GaInP, GaInAsP or any combination thereof.

The thickness of the first semiconductor layers 106 and the second semiconductor layers 108 may vary depending on the application and/or device performance considerations. In some embodiments, each first and second semiconductor layer 106, 108 has a thickness in a range between about 2 nm and about 30 nm. In other embodiments, each first and second semiconductor layer 106, 108 has a thickness in a range between about 3 nm and about 20 nm. In some embodiments, each first and second semiconductor layer 106, 108 has a thickness in a range between about 3 nm and about 10 nm. Each second semiconductor layer 108 may have a thickness that is equal to, less than, or greater than the thickness of the first semiconductor layer 106. The second semiconductor layers 108 may eventually be removed and serve to define a vertical distance between adjacent channels for the semiconductor device 100.

The first semiconductor layers 106 or portions thereof may form nanostructure channel(s) of the semiconductor device 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device 100 may be surrounded by a gate electrode. The semiconductor device 100 may include a nanostructure transistor. The nanostructure transistors may be referred to as nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device 100 is further discussed below.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes. While three first semiconductor layers 106 and three second semiconductor layers 108 are alternately arranged as illustrated in FIG. 2, it can be appreciated that any number of first and second semiconductor layers 106, 108 can be formed in the stack of semiconductor layers 104, depending on the predetermined number of nanostructure channels for each FET. For example, the number of first semiconductor layers 106, which is the number of channels, may be between 2 and 8.

In some embodiments, a hard mask layer (not shown) formed on the stack of semiconductor layers 104 is patterned using multiple patterning steps including photolithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches in unprotected regions through the hard mask layer, through the stack of semiconductor layers 104, and into the substrate 101, thereby leaving the plurality of extending fin structures 112. The trenches extend along the X direction. The trenches may be etched using a dry etch (e.g., RIE), a wet etch, and/or combination thereof.

In FIG. 3, one or more sacrificial gate structures 130 are formed above the semiconductor device 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Gate spacers 138 are then formed on sidewalls of the sacrificial gate structures 130. The gate spacers 138 may be formed by conformally depositing one or more layers for the gate spacers 138 and anisotropically etching the one or more layers, for example. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof.

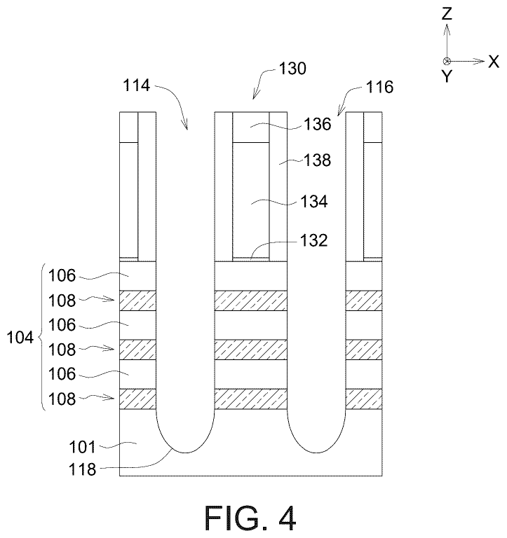

In FIG. 4, the portion of the fin structure 112 covered by the sacrificial gate electrode layer 134 of the sacrificial gate structure 130 is used as a channel region of the semiconductor device structure 100. The fin structures 112 that are exposed on opposite sides of the sacrificial gate structure 130 are removed to define source/drain (S/D) regions 114, 116 of the semiconductor device 100. In some cases, some source/drain regions 114, 116 may be shared between various transistors. For example, each of the source/drain regions 114, 116 may be connected together and implemented as a multifunctional transistor. The trench can be completed by an etching process, which can be dry etching or wet etching such as RIE, NBE or the like, such as using tetramethylammonium hydroxide (TMAH), ammonium hydroxide (NH₄OH) or any suitable etchant.

In FIG. 4, the trench depth of the source/drain regions 114 and 116 can be controlled by the etching process. In one embodiment, the bottom of the trench is lower than the upper surface of the substrate 101, for example. The etchant can reach down through the trench to the second semiconductor layer 108 at the bottom, and penetrate the second semiconductor layer 108 to etch the substrate 101.

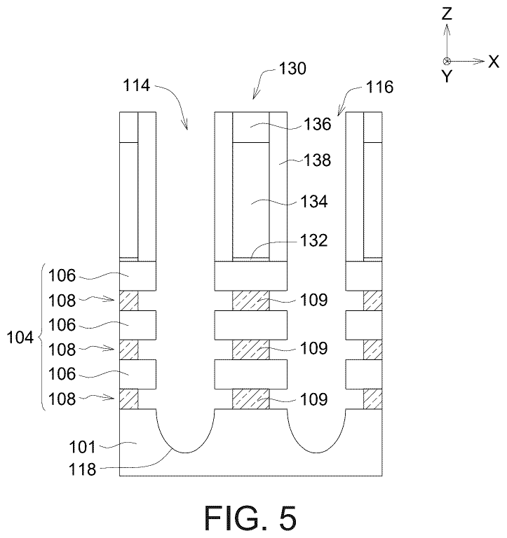

Referring to FIG. 5, edge portions of each second semiconductor layer 108 of the stack of semiconductor layers 104 are horizontally removed along the X direction to form a plurality of semiconductor nanosheets 109. In some embodiments, the edge portion of the second semiconductor layer 108 is removed through a selective wet etching process. In the case where the second semiconductor layer 108 is made of SiGe and the first semiconductor layer 106 is made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions. The removal of edge portions of the second semiconductor layers 108 expose side surfaces of the first semiconductor layers 106 along the X direction.

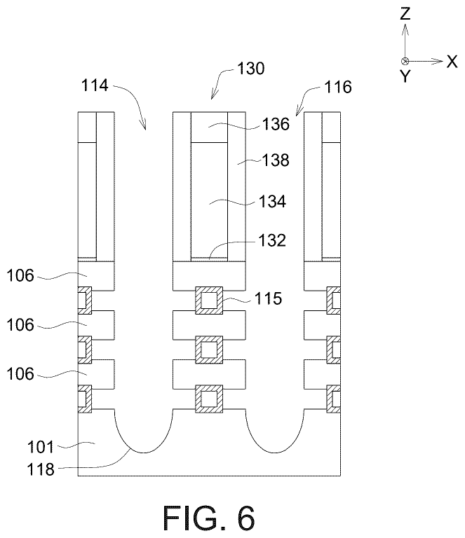

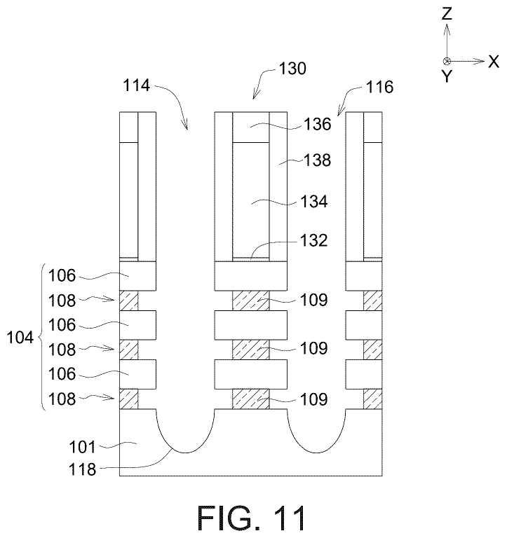

Referring to FIG. 6, each semiconductor interposer 109 is replaced by a sacrificial dielectric layer 115. That is to say, the semiconductor interposer 109 is first removed by an etching process, and then the sacrificial dielectric layer 115 is formed through the various stages described in FIGS. 11 to 16, which will be described later with reference to the drawings.

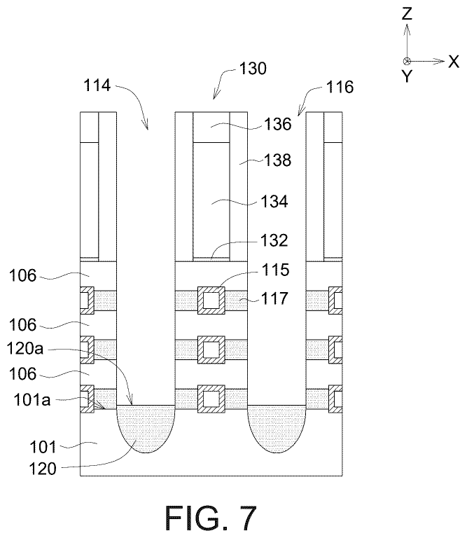

Referring to FIG. 7, a plurality of sacrificial inner spacers 117 (also called dummy inner spacers) is deposited in the cavities 111, and a separation layer 120 is formed in the trench 118 of the substrate 101. The sacrificial inner spacers 117 are located on opposite sides of the sacrificial dielectric layer 115, and the side surfaces of the sacrificial inner spacers 117 are substantially coplanar with the side surfaces of the first semiconductor layer 106. The sacrificial inner spacers 117 and separation layer 120 may be made of semiconductor materials. The first semiconductor layers 106 and the sacrificial inner spacers 117 are made of semiconductor materials with different etching selectivities and/or different oxidation rates. For example, the first semiconductor layers 106 may be made of Si, and the sacrificial inner spacers 117 and the separation layer 120 may be made of SiGe. In some examples, first semiconductor layer 106 may be made of silicon doped with Ge, and the sacrificial inner spacers 117 and the separation layer 120 may be made of SiGe. In some embodiments, the sacrificial inner spacers 117 and the separation layer 120 may be formed by a suitable epitaxial growth process.

In addition, the top surface 120a of the separation layer 120 may be slightly higher than the upper surface 101a of the substrate 101, so that the separation layer 120 and the lowermost sacrificial inner spacer 117 are connected to each other. That is, the level of the top surface 120a of the separation layer 120 is higher than the top level of the trench 118 of the substrate 101.

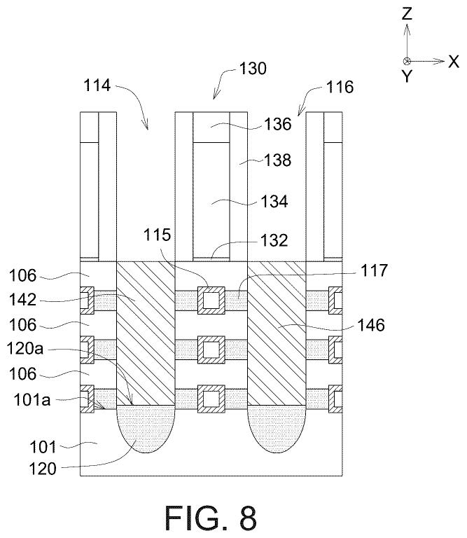

Referring to FIG. 8, in subsequent processes, epitaxial source/drain features 142, 146 are formed in the source/drain regions 114, 116. The sides of the epitaxial source/drain features 142, 146 are in contact with the first semiconductor layers 106 and the sacrificial inner spacers 117, and the bottoms of the epitaxial source/drain features 142, 146 are in contact with the separation layer 120. The epitaxial source/drain features 142, 146 may be made of one or more layers of Si, SiP, SiC, and SiCP for n-channel FETs, or Si, SiGe, Ge for p-type channel FETs. For p-type channel FETs, p-type dopants such as boron may also be included in the epitaxial source/drain features 142, 146. The epitaxial source/drain features 142, 146 may be formed on the epitaxial seed layer by epitaxial growth methods using chemical vapor deposition, atomic layer deposition, or molecular beam epitaxy. The epitaxial source/drain features 142, 146 may be grown vertically and horizontally to form facets, which may correspond to crystalline planes of the material used for the substrate 101. In some cases, the epitaxial source/drain features 142, 146 may be grown and merged with adjacent epitaxial source/drain features 142, 146. In some embodiments, prior to forming the epitaxial source/drain features 142, 146, a source/drain pre-clean process may be performed to remove native oxide formed on the first semiconductor layer 106 and the sacrificial inner spacers 117. The source/drain pre-cleaning process may be an inert gas sputtering process (e.g., argon sputtering) or a plasma-based cleaning process. In one embodiment, the source/drain pre-clean process is a Siconi™ process, which uses remote plasma to generate an ammonium fluoride (NH₄F) etchant from nitrogen trifluoride (NF₃) and ammonia (NH₃) to minimize the damage to semiconductor device 100.

In one example shown in FIG. 8, one of a pair of epitaxial source/drain features 142, 146 disposed on one side of the sacrificial gate structure 130 is designated as a source feature (source terminal), and the other of the pair of epitaxial source/drain features 142, 146 disposed on the other side of the sacrificial gate structure 130 is designated as a drain feature (drain terminal). The source feature (source terminal) and the drain feature (drain terminal) are connected by channel layers (e.g., the first semiconductor layers 106). The epitaxial source/drain features 142, 146 are in contact with the first semiconductor layer 106 under the sacrificial gate structure 130. In some cases, the epitaxial source/drain features 142, 146 may grow beyond the topmost semiconductor channel (i.e., the first semiconductor layer 106 below the sacrificial gate structure 130) to contact the gate spacer 138.

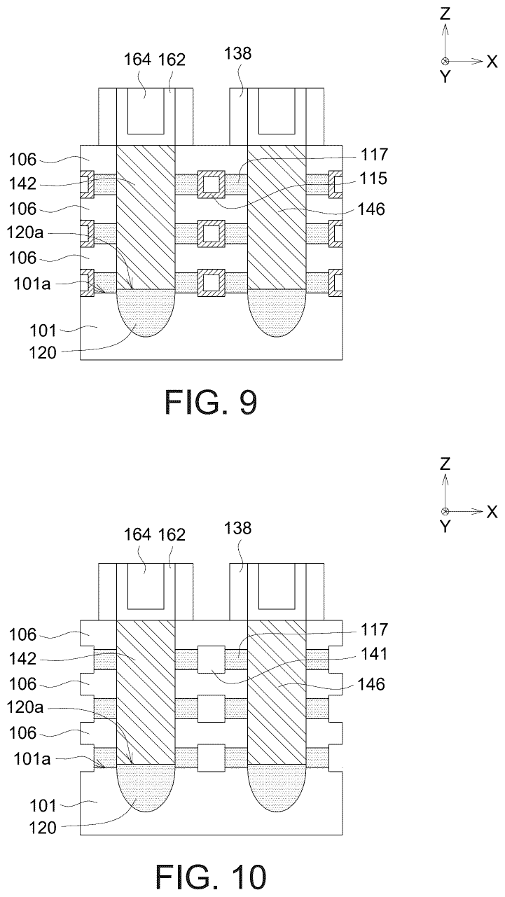

Referring to FIG. 9, in some embodiments, a contact etch stop layer (CESL) 162 is conformally formed on the exposed surface of the semiconductor device. The contact etch stop layer 162 covers the sidewalls of sacrificial gate structure 130 and the upper surfaces of epitaxial source/drain features 142, 146. The contact etch stop layer 162 may include an oxygen-containing material or a nitrogen-containing material, such as silicon nitride, silicon carbonitride, silicon oxynitride, silicon carbonitride, silicon oxide, silicon oxycarbide, the like, or combinations thereof, and may formed by CVD, PECVD, ALD or any suitable deposition technology. Next, a first interlayer dielectric (ILD) 164 is formed on the contact etch stop layer 162 above the semiconductor device 100. The material of the first interlayer dielectric layer 164 may include compounds including Si, O, C, and/or H, such as silicon oxide, ethyl orthosilicate oxide, SiCOH, and SiOC. Organic materials such as polymers may also be used for the first interlayer dielectric layer 164. The first interlayer dielectric layer 164 may be deposited by a PECVD process or other suitable deposition techniques. In some embodiments, after forming the first interlayer dielectric layer 164, the semiconductor device 100 may undergo a thermal process to anneal the first interlayer dielectric layer 164.

In addition, in FIG. 9, plasma dry etching and/or wet etching may also be used to remove the sacrificial gate structure 130. The sacrificial gate electrode layer 134 may first be removed by any suitable process, such as dry etching, wet etching, or a combination thereof. The sacrificial gate dielectric layer 132 is then removed by performing any suitable process (such as dry etching, wet etching, or a combination thereof). In some embodiments, a wet etchant, such as a tetramethylammonium hydroxide (TMAH) solution, may be used to selectively remove the sacrificial gate electrode layer 134 but not the gate spacers 138, the first interlayer dielectric layer 164 and the contact etch stop layer 162.

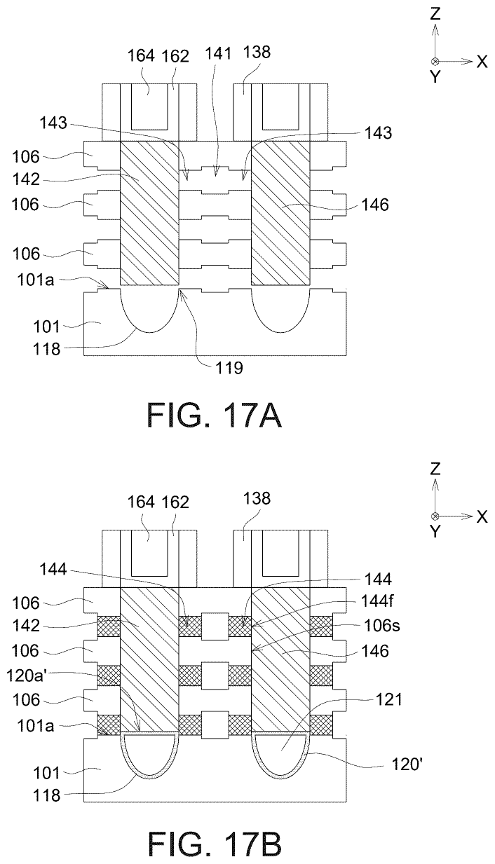

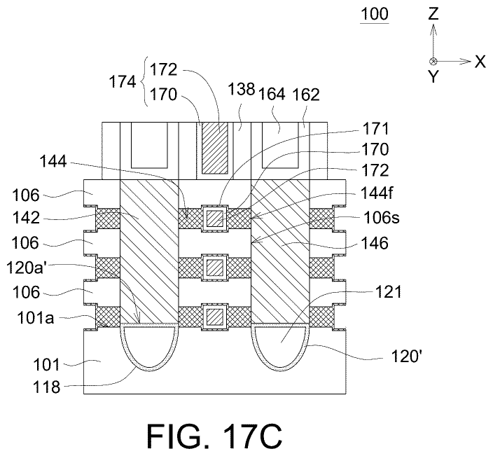

Referring to FIG. 10, after removing the sacrificial gate structure 130, the sacrificial dielectric layers 115 between the first semiconductor layers 106 are removed to form a plurality of cavities 141. Later, the sacrificial inner spacers 117 may be replaced by dielectric spacers 144 so that the dielectric spacers 144 are located on opposite sides of the epitaxial source/drain features 142 and 146. For embodiments of various stages in which the sacrificial inner spacers 117 are replaced by dielectric spacers 144, please refer to FIGS. 17A to 17C, 18A to 18F, and 19A to 19C.

FIGS. 11 to 16 respectively illustrate B-B′ cross-sectional schematic diagrams at various stages for replacing semiconductor nanosheets 109 in FIG. 5 with sacrificial dielectric layers 115 in FIG. 6 according to embodiments of the present disclosure.

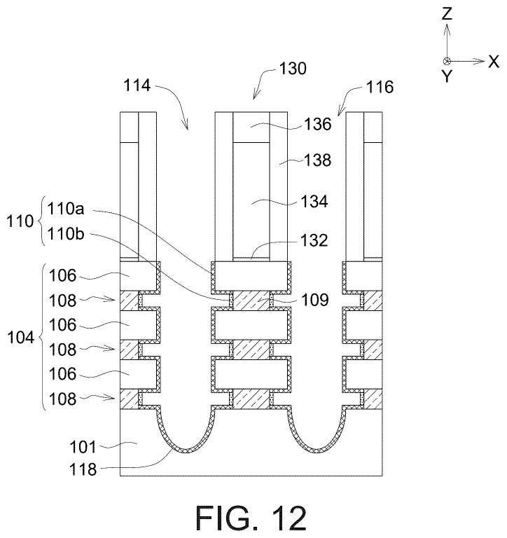

Referring to FIG. 11, edge portions of each second semiconductor layer 108 of the stack of semiconductor layers 104 are horizontally removed along the X direction to form a plurality of semiconductor nanosheets 109 located between the first semiconductor layers 106. Referring to FIG. 12, an interfacial layer 110 is formed on the exposed surfaces of the first semiconductor layers 106 and the semiconductor nanosheets 109. In some embodiments, the interfacial layer 110 is formed by, for example, thermal oxidation. The interfacial layer 110 includes a first oxide 110a formed on the first semiconductor layer 106 and a second oxide (i.e., semipermeable films 110b) formed on the semiconductor nanosheets 109. The first oxide 110a and the second oxide are, for example, silicon oxide, but the first oxide 110a and the second oxide have different air permeabilities due to different silicon contents. The first oxide 110a is formed on the first semiconductor layers 106 with more silicon contents than the semiconductor nanosheets 109 so that the first oxide 110a has more silicon content than the second oxide 110b. The first oxide 110a is, for example, a silicon oxide layer formed by the oxidation of silicon atoms on the surface of the first semiconductor layer 106, and the second oxide is, for example, a semipermeable film 110b with porous silicon oxide. The chemical etchant can pass through the semipermeable film 110b with porous silicon oxide, but cannot pass through the first oxide 110a, so that the chemical etchant can only etch the semiconductor nanosheets 109 but cannot etch the first semiconductor layers 106.

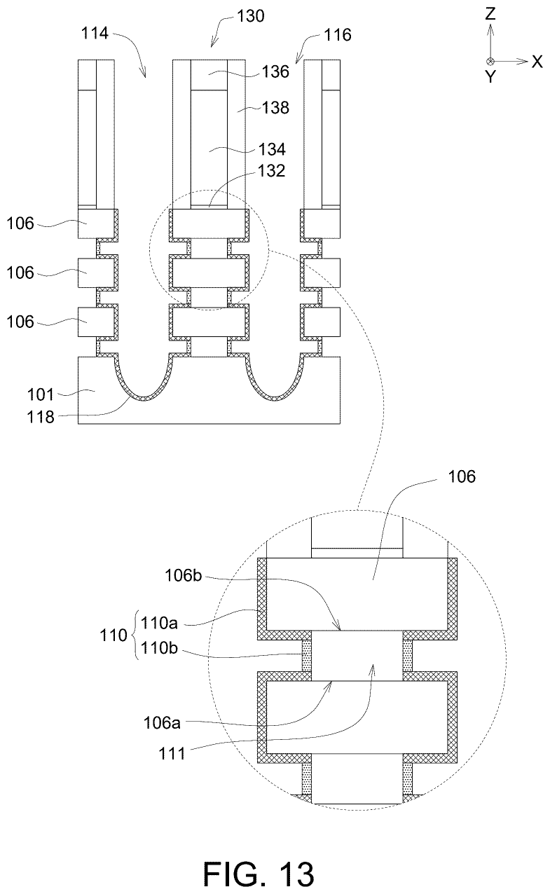

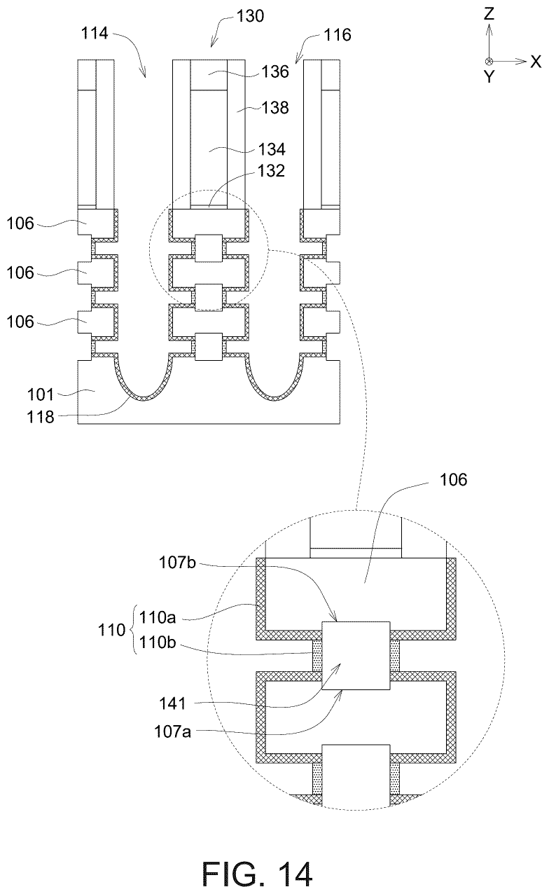

Referring to FIG. 13, the chemical etchant selectively etches the semiconductor nanosheets 109 between the first semiconductor layers 106 to form a plurality of cavities 111 between the first semiconductor layers 106. Next, referring to FIG. 14, the chemical etchant can further etch a portion of the upper surface 106a and a portion of the lower surface 106b of the first semiconductor layer 106 that is not covered by the first oxide 110a, so that each of the first semiconductor layers 106 has a first part 107a and a second part 107b inwardly recessed. The first part 107a and the second part 107b are opposite to each other to increase the height of the cavity 141 in the vertical direction.

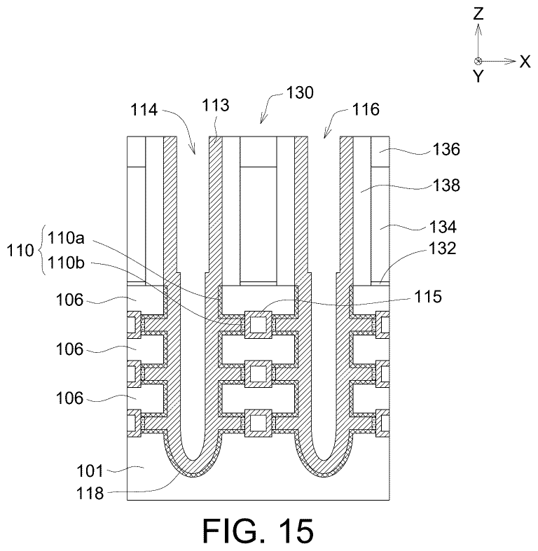

Referring to FIG. 15, a plurality of liners 113 are deposited in the trenches defined by the source/drain regions 114 and 116, and a plurality of sacrificial dielectric layers 115 are deposited in the cavities 141 defined by the semipermeable films 110b. In some embodiments, the liners 113 and the sacrificial dielectric layer 115 are formed by, for example, PVD, CVD or other suitable deposition processes. The deposit is, for example, a dielectric material containing silicon. The deposit can enter the cavities 141 through the semipermeable film 110b (i.e, the second oxide) with porous silicon oxide, and be deposited on exposed surfaces of the semipermeable films 110b and the first portion 107a and the second portion 107b of the first semiconductor layers 106 to serve as the sacrificial dielectric layers 115.

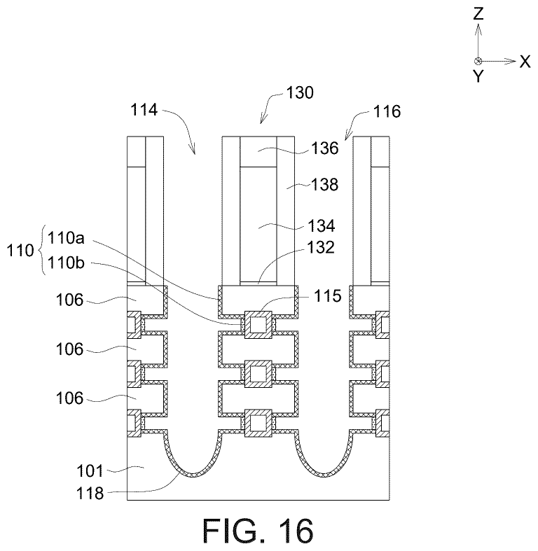

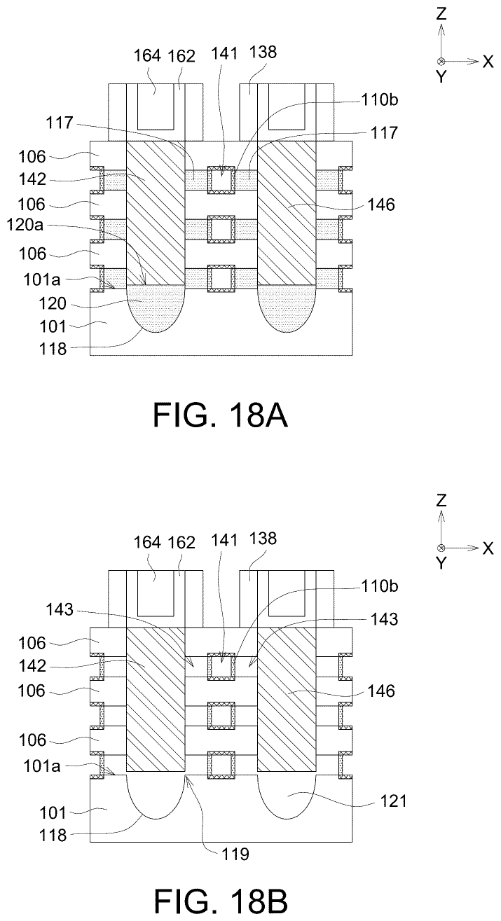

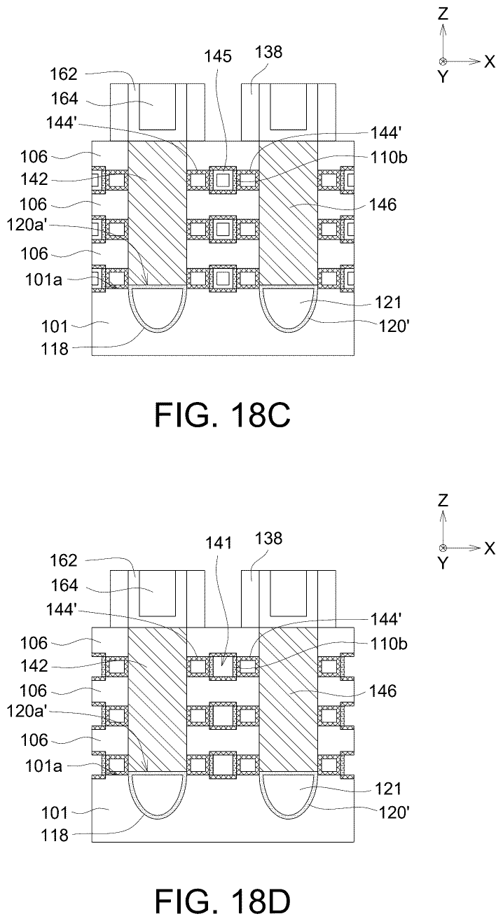

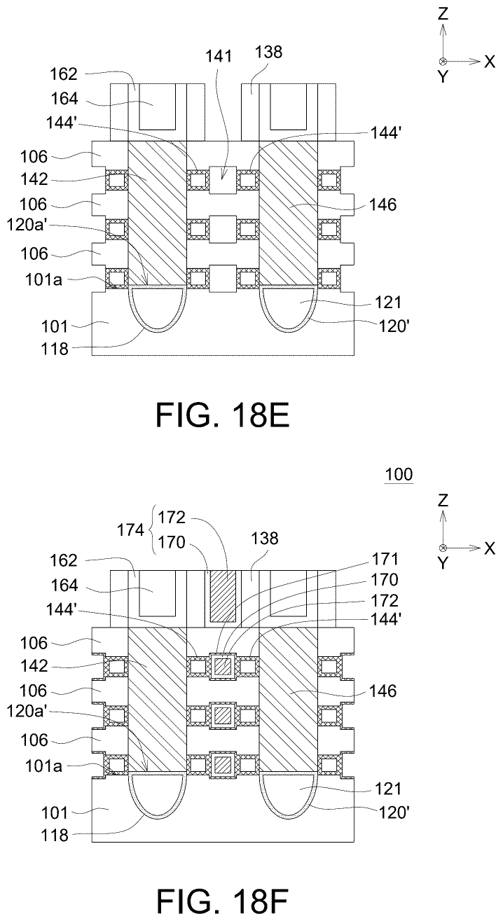

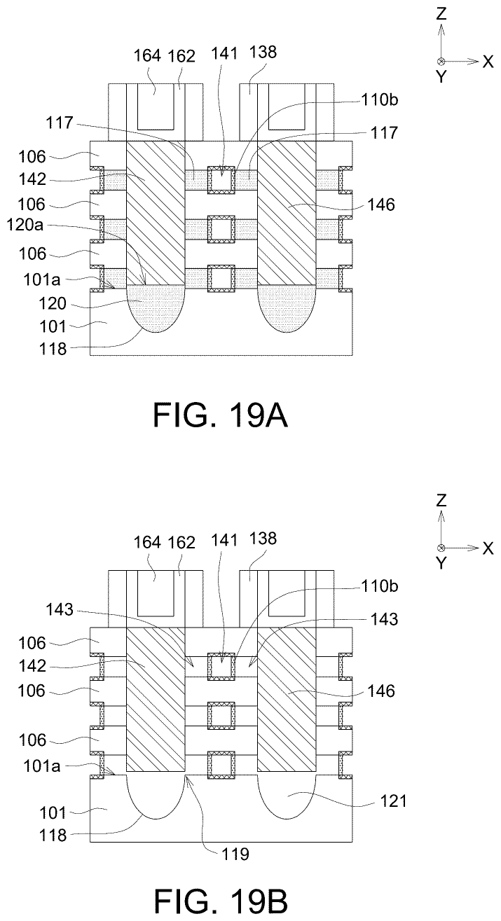

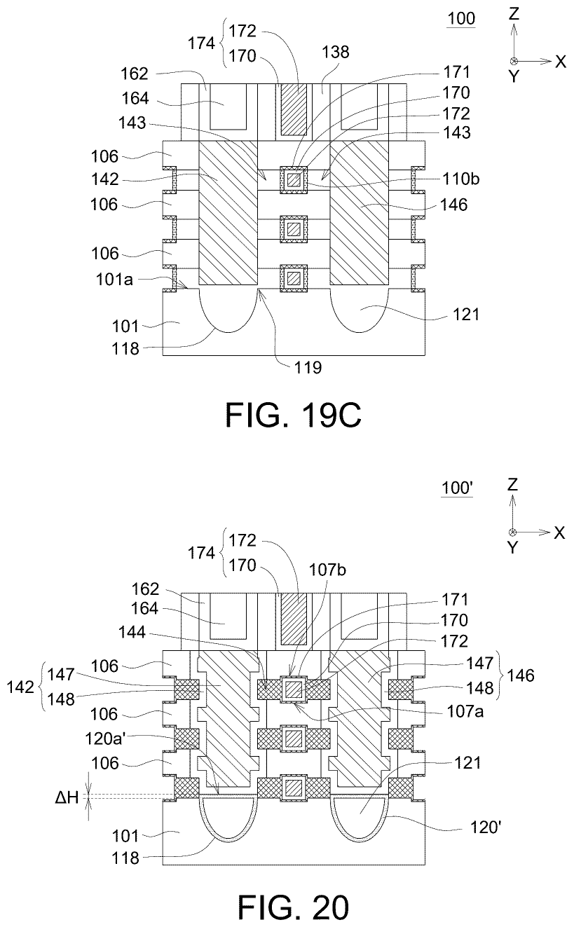

Referring to FIG. 16, the liners 113 are etched to remove deposits covering the trenches defined by the source/drain regions 114, 116, but does not remove the sacrificial dielectric layers 115. That is, the chemical etchant cannot pass through the semipermeable film 110b with porous silicon oxide, so the sacrificial dielectric layer 115 will not be removed. In FIG. 16, the semipermeable film 110 b with porous silicon oxide can be removed (see FIGS. 17A to 17C), or the semipermeable film 110 b can be retained for subsequent processes (see FIGS. 18A to 18F or 19A to 19C), the present disclosure is not limited thereto.

From the above description, it can be known that the semiconductor nanosheets 109 in FIG. 5 can be replaced by the sacrificial dielectric layers 115 in FIG. 6 through various steps of FIG. 11 to FIG. 16.

Next, FIGS. 17A to 17C respectively illustrate B-B′ cross-sectional schematic diagrams at various stages for replacing the sacrificial inner spacers 117 in FIG. 10 with dielectric inner spacers 144 according to the first embodiment of the present disclosure. Referring to FIGS. 10 and 17A, after the epitaxial source/drain features 142 and 146 are completed, the sacrificial inner spacers 117 and the separation layer 120 are removed to expose the sides and bottoms of epitaxial source/drain features 142 and 146 and a plurality of inner spaces 143 is formed on opposite sides of the epitaxial source/drain features 142 and 146. The method of removing the sacrificial inner spacers 117 and the separation layer 120 includes wet etching. The chemical etchant can enter the cavities 141 after the sacrificial dielectric layers 115 are removed in FIG. 10 to etch the sacrificial inner spacers 117. After the sacrificial inner spacers 117 are removed, the chemical etchant enters the trench 118 of the substrate 101 through the connection gap 119 between the inner spaces 143 and the trench 118 to etch the separation layer 120 in FIG. 10.

Referring to FIG. 17B, a deposition process is performed to form a plurality of dielectric spacers 144 on opposite sides of the epitaxial source/drain features 142, 146. In addition, the deposit can enter the trench 118 of the substrate 101 through the connection gap 119 between the inner spaces 143 and the trench 118 of the substrate 101 to form a bottom dielectric layer 120′ in the trench 118 of the substrate 101. The top surface 120a′ of the bottom dielectric layer 120′ may be slightly higher than the top surface of the substrate 101, so that the bottom dielectric layer 120′ and the lowermost dielectric spacers 144 are connected to each other. That is, the level of the top surface of the bottom dielectric layer 120′ is higher than the top level of the trench 118 of the substrate 101.

The bottom dielectric layer 120′ is used to isolate the bottom surface of the epitaxial source/drain features 142, 146 from the substrate 101 to avoid leakage current. In some embodiments, the bottom dielectric layer 120′ is a hollow dielectric structure wrapped around a low-k substance (such as air 121) to reduce the dielectric constant of the separation layer. Additionally, the dielectric spacers 144 may be made of a low-k dielectric material, such as SiON, SiCN, SiOC, SiOCN, or SiN. In some embodiments, the dielectric spacers 144 are formed from a material having a dielectric constant in the range of 3.5 to 5.5. The dielectric spacers 144 may be formed by atomic layer deposition, pulsed plasma chemical vapor deposition, or any suitable deposition process. The end portion 144f of the dielectric spacers 144 between the first semiconductor layers 106 may have a flat surface or a circular arc surface, and the flat surface is substantially coplanar with the side surfaces 106s of the first semiconductor layers 106.

Referring to FIG. 17C, after the dielectric spacers 144 are formed, a gate dielectric layer 170 is formed to surround the first semiconductor layer 106, and a gate electrode layer 172 is formed on the gate dielectric layer 170. The gate dielectric layer 170 and the gate electrode layer 172 may be collectively referred to as a gate structure 174. In some embodiments, an interfacial layer 171 (IL) is formed between the gate dielectric layer 170 and the exposed surface of the first semiconductor layers 106. In this case, the interfacial layer 171 may also be formed on the well portion of the substrate 101. The interfacial layer 171 may include or be made of oxygen-containing materials or silicon-containing materials, such as silicon oxide, silicon oxynitride, oxynitride, hafnium silicate, and the like. The interfacial layer 171 can be formed by CVD, ALD, cleaning process or any suitable process. In some embodiments, gate dielectric layer 170 includes one or more layers of dielectric materials, such as silicon oxide, silicon nitride, high-k dielectric materials, other suitable dielectric materials, and/or combinations thereof. Examples of high-k dielectric materials include HfO₂, HfSiO, HfSiON, HfTaO, HfTiO, HfZrO, zirconium oxide, alumina, titanium oxide, hafnium dioxide-aluminum oxide (HfO₂—Al₂O₃) alloy, and other suitable high-k dielectric materials and/or combinations thereof. The gate dielectric layer 170 may be formed by CVD, ALD, or any suitable deposition technique.

The gate electrode layer 172 may include one or more layers of conductive materials, such as polycrystalline silicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials and/or any combination thereof. The gate electrode layer 172 may be formed by CVD, ALD, electroplating or other suitable deposition techniques. The gate electrode layer 172 may also be deposited over the upper surface of first interlayer dielectric layer 164. Next, the gate dielectric layer 170 and the gate electrode layer 172 formed over the first interlayer dielectric layer 164 are removed by using, for example, chemical mechanical polishing until the top surface of the first interlayer dielectric layer 164 is exposed.

FIGS. 18A to 18F respectively illustrate B-B′ cross-sectional schematic diagrams of various stages for replacing the sacrificial inner spacers 117 in FIG. 10 with dielectric hollow inner spacers 144′ according to a second embodiment of the present disclosure. This embodiment is performed while retaining the semipermeable films 110b with porous silicon oxide. Please refer to FIGS. 11 to 16 for the related process of manufacturing the semipermeable film 110b. Referring to FIGS. 18A and 18B, after the epitaxial source/drain features 142 and 146 are completed, the sacrificial inner spacers 117 and the separation layer 120 are removed, but the semipermeable films 110b is not removed to form a plurality of inner spaces 143 defined by the semipermeable films 110b and located on opposite sides of the epitaxial source/drain features 142, 146, and expose the sides and bottoms of the epitaxial source/drain features 142, 146. The method of removing the sacrificial inner spacers 117 and the separation layer 120 includes wet etching. The chemical etchant can enter the inner spaces 143 through the cavities 141 after the sacrificial dielectric layer 115 is removed in FIG. 10 to etch the sacrificial inner spacers 117. After the sacrificial inner spacers 117 is removed, the chemical etchant enters the trench 118 of the substrate 101 through the connection gap 119 between the spacing spaces 143 and the trench 118 to etch the separation layer 120.

Referring to FIG. 18C, a deposition process is performed to form a plurality of dielectric spacers 144′ the on opposite sides of the epitaxial source/drain features 142, 146 and deposited in the spacing spaces 143. In addition, the deposit can enter the trench 118 of the substrate 101 through the connection gap 119 between the inner spaces 143 and the trench 118 of the substrate 101 to form a bottom dielectric layer 120′ in the trench 118 of the substrate 101. The top surface 120a′ of the bottom dielectric layer 120′ may be slightly higher than the top surface of the substrate 101, so that the bottom dielectric layer 120′ and the lowermost dielectric spacers 144′ are connected to each other. In some embodiments, the bottom dielectric layer 120′ is a hollow dielectric structure wrapped around a low-k dielectric substance (such as air 121) to reduce the dielectric constant of the overall separation layer. Additionally, the dielectric spacers 144′ may be made of a low-k dielectric material, such as SiON, SiCN, SiOC, SiOCN, or SiN. In some embodiments, the dielectric spacers 144′ are formed from a material having a dielectric constant in the range of 3.5 to 5.5.

Referring to FIG. 18C, each of the dielectric spacers 144′ can be a hollow spacer wrapped around a low-k dielectric substance (such as air) to reduce the dielectric constant of the overall spacers. In addition, during the deposition process, excess deposits 145 may be formed in the cavities 141. Referring to FIG. 18D, an etching process is performed to remove excess deposits 145. In FIG. 18D, since the semipermeable films 110b with porous silicon oxide can block the chemical etchant, the chemical etchant cannot pass through the semipermeable films 110b with porous silicon oxide. Next, referring to FIG. 18E, the semipermeable films 110b with porous silicon oxide are removed, for example, etched. The etching process may include dry etching, wet etching, reactive ion etching (RIE) and/or other suitable processes.

Referring to FIG. 18F, after removing the semipermeable films 110b with porous silicon oxide, a gate dielectric layer 170 is formed to surround the first semiconductor layers 106, and a gate electrode layer 172 is formed on the gate dielectric layer 170. The gate dielectric layer 170 and the gate electrode layer 172 may be collectively referred to as a gate structure 174. In some embodiments, an interfacial layer 171 (IL) is formed between the gate dielectric layer 170 and the exposed surface of the first semiconductor layers 106. In this case, the interfacial layer 171 may also be formed on the well portion of the substrate 101. The interfacial layer 171 may include or be made of oxygen-containing materials or silicon-containing materials, such as silicon oxide, silicon oxynitride, oxynitride, hafnium silicate, and the like. The interfacial layer 171 can be formed by CVD, ALD, cleaning process or any suitable process.

FIGS. 19A to 19C respectively illustrate B-B′ cross-sectional schematic diagrams of various stages for replacing the sacrificial inner spacers 117 in FIG. 10 with full air inner spacers according to a third embodiment of the present disclosure. This embodiment is performed while retaining the semipermeable films 110b with porous silicon oxide. Please refer to FIGS. 11 to 16 for the related processes of manufacturing the semipermeable films 110b. Referring to FIGS. 19A and 19B, after the epitaxial source/drain features 142 and 146 are completed, the sacrificial inner spacers 117 and the separation layer 120 are removed, but the semipermeable films 110b are not removed to form a plurality of inner spaces 143 defined by the semipermeable films 110b on opposite sides of the epitaxial source/drain features 142 and 146 and expose the sides and bottoms of the epitaxial source/drain features 142 and 146. The method of removing the sacrificial inner spacers 117 and the separation layer 120 includes wet etching. The chemical etchant can enter the inner spaces 143 through the cavities 141 after the sacrificial dielectric layers 115 are removed in FIG. 10 to etch the sacrificial inner spacers 117. After the sacrificial inner spacers 117 are removed, the chemical etchant enters the trench 118 of the substrate 101 through the connection gap 119 between the inner spaces 143 and the trench 118 to etch the separation layer 120.

Referring to FIG. 19C, a deposition process is performed to form a gate dielectric layer 170 to surround the first semiconductor layers 106, and a gate electrode layer 172 is formed on the gate dielectric layer 170. The gate dielectric layer 170 and the gate electrode layer 172 may be collectively referred to as a gate structure 174. In some embodiments, an interfacial layer 171 (IL) is formed between the gate dielectric layer 170 and the exposed surface of the first semiconductor layers 106. In this case, the interfacial layer 171 may also be formed on the well portion of the substrate 101. The interfacial layer 171 may include or be made of oxygen-containing materials or silicon-containing materials, such as silicon oxide, silicon oxynitride, oxynitride, hafnium silicate, and the like. The interfacial layer 171 can be formed by CVD, ALD, cleaning process or any suitable process.

In FIG. 19C, since the semipermeable films 110b with porous silicon oxide can prevent deposits from entering the inner spaces 143, there is only air with a low dielectric constant in the inner spaces 143 as a dielectric spacer to reduce the dielectric constant of the dielectric spacers. In addition, there is no substance deposited in the trench 118 below the epitaxial source/drain features 142, 146, and only air 121 with a low dielectric constant in the trench 118 is used as a bottom separation layer to reduce the dielectric constant of the bottom separation layer.

FIGS. 20 to 22 respectively illustrate B-B′ cross-sectional schematic diagrams of semiconductor devices 100′ according to embodiments of the present disclosure. Referring to FIGS. 20 and 22, each of the epitaxial source/drain features 142 and 146 may include a first p-type doped epitaxial layer 147 and a second p-type doped epitaxial layer 148 surrounding the first p-type doped epitaxial layer 147. The first p-type doped epitaxial layer 147 and the second p-type doped epitaxial layer 148 may include silicon germanium (SiGe) or silicon doped with boron or gallium. The dopant type and concentration of the first p-type doped epitaxial layer 147 are different from the dopant type and concentration of the second p-type doped epitaxial layer 148. The doping concentration is, for example, between 1E17 and 8E22. The thickness of the second p-type doped epitaxial layer 148 may be 0.5 nm to 10 nm.

Referring to FIG. 20, the manufacturing method of the semiconductor device 100′ is similar to that of the semiconductor device 100. Please refer to FIGS. 17A to 17C. The bottom dielectric layer 120′ is a hollow dielectric structure wrapped around a low-k dielectric substance (such as air 121) to reduce the dielectric constant of the bottom separation layer. The first semiconductor layer 106 has a first portion 107a and a second portion 107b that are recessed inward to form a bow-tie structure in the horizontal direction. The depth of the recess may be 0.5 nm to 2 nm. In addition, the bottom surfaces of the epitaxial source/drain features 142 and 146 are higher than the upper surface of the substrate 101. For example, the height difference ΔH is about 1 to 5 nm, and the bottom surfaces of the epitaxial source/drain features 142 and 146 are not connected to the substrate 101 to avoid leakage current.

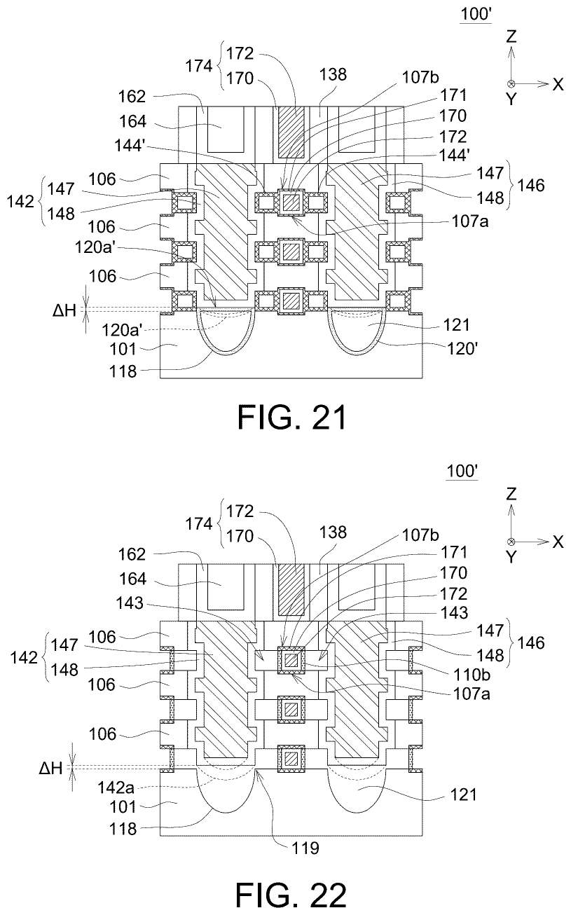

Referring to FIG. 21, the manufacturing method of the semiconductor device 100′ is similar to that of the semiconductor device 100. Please refer to FIGS. 18A to 18F. The dielectric spacers 144′ can be a hollow spacer that wrapped around a low-k dielectric substance (such as air) to reduce the dielectric constant of the overall spacer. The first semiconductor layer 106 has a first portion 107a and a second portion 107b that are recessed inward to form a bow-tie structure in the horizontal direction. The depth of the recess may be 0.5 nm to 2 nm. In addition, the bottom surfaces of the epitaxial source/drain features 142 and 146 are higher than the upper surface of the substrate 101. For example, the height difference ΔH is about 1 to 5 nm, and the bottom surfaces of the epitaxial source/drain features 142 and 146 are not connected to the substrate 101 to avoid leakage current. In one embodiment, the top surface 120a′ of the bottom dielectric layer 120′ may be slightly higher than the top surface of the substrate 101, and the top surface 120a′ may have a flat shape or an arc shape (as indicated by the dotted line). The center of the arc-shaped top surface 120a′ may be lower than that of the top surface of the substrate 101.

Referring to FIG. 22, for the manufacturing method of the semiconductor device 100′ is similar to that of the semiconductor device 100. Please refer to FIGS. 19A to 19C. The semipermeable films 110b with porous silicon oxide are used to define inner spaces 143 on opposite sides of the epitaxial source/drain features 142, 146. Therefore, there is only air of a low dielectric constant as a medium in the inner spaces 143 to reduce the dielectric constant of the dielectric spacers. In addition, there is no substance deposited in the trench 118 below the epitaxial source/drain features 142, 146, and only air 121 as a bottom separation layer to reduce the dielectric constant of the bottom separation layer. In addition, the first semiconductor layer 106 has a first portion 107a and a second portion 107b that are recessed inward to form a bow-tie structure in the horizontal direction, and the depth of the recess may be 0.5 nm to 2nm. In addition, the bottom surfaces of the epitaxial source/drain features 142 and 146 are higher than the upper surface of the substrate 101. For example, the height difference ΔH is about 1 to 5 nm, and the bottom surfaces of the epitaxial source/drain features 142 and 146 are not connected to the substrate 101 to avoid leakage current. In one embodiment, the bottom surfaces 142a of the pitaxial source/drain features 142 and 146 may have a flat shape or an arc shape (as indicated by the dotted line). The center of the arc-shaped bottom surface 142a may be convex and lower than that of the top surface of the substrate 101.

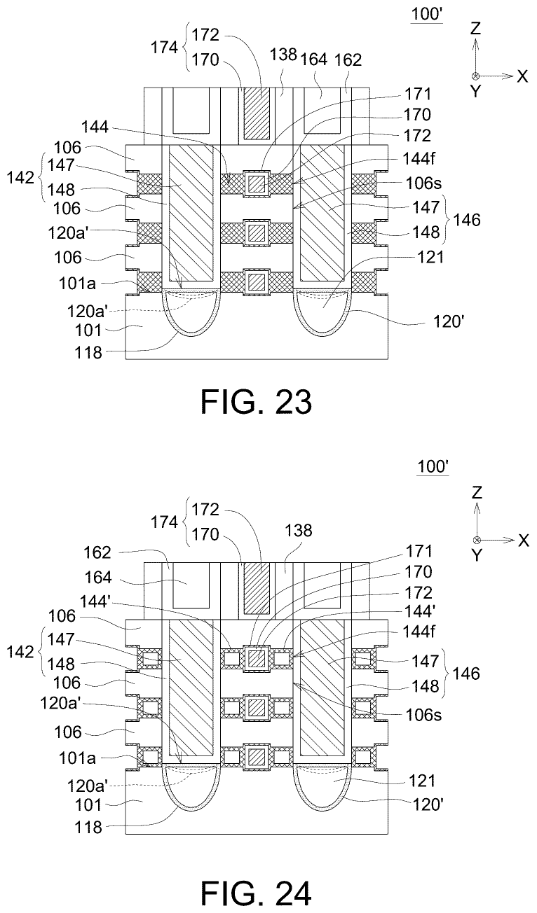

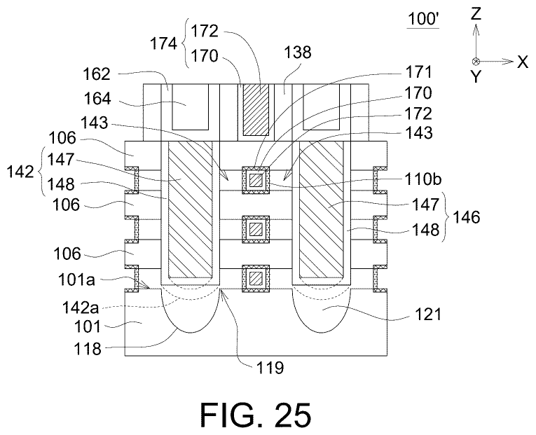

FIGS. 23 to 25 respectively illustrate B-B′ cross-sectional schematic diagrams of semiconductor devices 100′ according to other embodiments of the present disclosure. Referring to FIGS. 23 and 25, each of the epitaxial source/drain features 142 and 146 may include a first p-type doped epitaxial layer 147 and a second p-type doped epitaxial layer 148 surrounding the first p-type doped epitaxial layer 147. The first p-type doped epitaxial layer 147 and the second p-type doped epitaxial layer 148 may include silicon germanium (SiGe) or silicon doped with boron or gallium. The dopant type and concentration of the first p-type doped epitaxial layer 147 are different from the dopant type and concentration of the second p-type doped epitaxial layer 148. The doping concentration is, for example, between 1E17 and 8E22. The thickness of the second p-type doped epitaxial layer 148 may be 0.5 nm to 10 nm.

In one embodiment, the profiles of the first p-type doped epitaxial layer 147 and the second p-type doped epitaxial layer 148 may be straight instead of convex profile shown in FIGS. 20-22. The manufacturing method of the semiconductor device 100′ shown in FIG. 23 is similar to that of the semiconductor device 100 except the epitaxial source/drain features 142 and 146, with reference to FIGS. 17A to 17C. The manufacturing method of the semiconductor device 100′ shown in FIG. 24 is similar to that of the semiconductor device 100 except the epitaxial source/drain features 142 and 146, with reference to FIGS. 18A to 18F.

The manufacturing method of the semiconductor device 100′ shown in FIG. 25 is similar to that of the semiconductor device 100 except the epitaxial source/drain features 142 and 146, with reference FIG. 19A 19C. In one embodiment, the bottom surfaces 142a of the pitaxial source/drain features 142 and 146 may have a flat shape or an arc shape (as indicated by the dotted line).

The present disclosure is directed to a semiconductor device and a manufacturing method thereof. A plurality of sacrificial inner spacers (such as dummy SiGe spacers) and a separation layer (such as hollow dielectric layer or full air separation) are formed to improve source/drain epitaxy quality and lower the dielectric constant of the separation layer between the epitaxial source/drain feature and the substrate. In addition, a connection gap is formed between the bottom of the epitaxial source/drain feature and the trench so that the bottom dielectric layer can be formed in the trench of the substrate through the connection gap. The bottom dielectric layer may be a hollow dielectric structure wrapped around a low-k dielectric substance (such as air) or have only air to reduce the dielectric constant of the separation layer.

According to some embodiments of the present disclosure, a method for manufacturing a semiconductor device is provided with the following steps. A plurality of first semiconductor layers and a plurality of second semiconductor layers alternately stacked on a substrate are formed. Edge portions of the second semiconductor layers are removed to form a plurality of semiconductor nanosheets between the first semiconductor layers. A plurality of semipermeable films is formed on sidewalls of the semiconductor nanosheets. The semiconductor nanosheets is removed to form a plurality of cavities between the first semiconductor layers. A plurality of sacrificial dielectric layers is deposited in the cavities defined by the semipermeable films.

According to some embodiments of the present disclosure, a method for manufacturing a semiconductor device is provided with the following steps. A plurality of first semiconductor layers and a plurality of second semiconductor layers alternately stacked on a substrate are formed. Edge portions of the second semiconductor layers are removed to form a plurality of semiconductor nanosheets between the first semiconductor layers. A plurality of semipermeable films is formed on sidewalls of the semiconductor nanosheets. The semiconductor nanosheets are removed to form a plurality of cavities between the first semiconductor layers. A plurality of sacrificial inner spacers is formed in a plurality of inner spaces defined by the semipermeable films. A separation layer is formed in a trench of the substrate, and the separation layer is connected to a lowermost one of the sacrificial inner spacers. An epitaxial source/drain feature is formed such that the sides of the epitaxial source/drain features are in contact with the first semiconductor layers and the sacrificial inner spacers, and the bottoms of the epitaxial source/drain features are in contact with the separation layer.

According to some embodiments of the present disclosure, a semiconductor device comprises a substrate, a first epitaxial source/drain feature, a second epitaxial source/drain feature, two or more semiconductor layers, and a plurality of dielectric spacers. The substrate has a trench and a separation layer located in the trench, and a top surface of the separation layer is higher than a top surface of the substrate. The first and second epitaxial source/drain features are formed on the separation layer. The two or more semiconductor layers are electrically connected between the first epitaxial source/drain feature and the second epitaxial source/drain feature. The plurality of dielectric spacers is located between the two or more semiconductor layers, the dielectric spacers are located between two opposite sides of the first epitaxial source/drain feature and the second epitaxial source/drain feature, wherein a lowermost one of the dielectric spacers is connected to the separation layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a plurality of first semiconductor layers and a plurality of second semiconductor layers alternately stacked on a substrate;
removing edge portions of the second semiconductor layers to form a plurality of semiconductor nanosheets between the first semiconductor layers;
forming a plurality of semipermeable films on sidewalls of the semiconductor nanosheets;
removing the semiconductor nanosheets to form a plurality of cavities between the first semiconductor layers; and
depositing a plurality of sacrificial dielectric layers in the cavities defined by the semipermeable films.

2. The method of claim 1, further comprising:
forming a plurality of sacrificial inner spacers on opposite sides of the sacrificial dielectric layers;
forming a separation layer in a trench of the substrate, the separation layer is connected to a lowermost one of the sacrificial inner spacers; and
forming an epitaxial source/drain feature such that sides of the epitaxial source/drain feature are in contact with the first semiconductor layers and the sacrificial inner spacers, and a bottom of the epitaxial source/drain feature is in contact with the separation layer.

3. The method of claim 2, wherein a top surface of the separation layer is higher than an upper surface of the substrate, and a connection gap is formed between the bottom of the epitaxial source/drain feature and the trench.

4. The method of claim 3, further comprising:
removing the sacrificial dielectric layers;
removing the sacrificial inner spacers and the separation layer to expose the sides and the bottom of the epitaxial source/drain feature;
forming a plurality of dielectric spacers on opposite sides of the epitaxial source/drain feature; and
forming a bottom dielectric layer in the trench of the substrate through the connection gap, and the bottom dielectric layer is connected to a lowermost one of the dielectric spacers.

5. The method of claim 4, wherein the bottom dielectric layer is a hollow dielectric structure containing air.

6. The method of claim 4, wherein a top surface of the bottom dielectric layer is higher than a top surface of the substrate.

7. The method of claim 3, further comprising:
removing the sacrificial dielectric layers;
removing the sacrificial inner spacers and the separation layer to expose the sides and bottom of the epitaxial source/drain feature;
forming a plurality of inner spaces defined by the semipermeable films on opposite sides of the epitaxial source/drain feature;
forming a plurality of dielectric spacers on opposite sides of the epitaxial source/drain feature and deposited in the inner spaces; and
forming a bottom dielectric layer in the trench of the substrate through the connection gap, and the bottom dielectric layer is connected to a lowermost one of the dielectric spacers.

8. The method of claim 7, wherein the bottom dielectric layer is a hollow dielectric structure containing air.

9. The method of claim 7, wherein a top surface of the bottom dielectric layer is higher than a top surface of the substrate.

10. The method of claim 7, wherein the dielectric spacers are hollow spacers, and the hollow spacers contain air.

11. The method of claim 3, further comprising:
removing the sacrificial dielectric layers;
removing the sacrificial inner spacers and the separation layer to expose the sides and bottom of the epitaxial source/drain feature; and
forming a plurality of inner spaces defined by the semipermeable films on opposite sides of the epitaxial source/drain feature.

12. The method of claim 11, wherein the separation inner spaces contain air, and the trench of the substrate contains air.

13. A method for manufacturing a semiconductor device, comprising:
forming a plurality of first semiconductor layers and a plurality of second semiconductor layers alternately stacked on a substrate;
removing edge portions of the second semiconductor layers to form a plurality of semiconductor nanosheets between the first semiconductor layers;
forming a plurality of semipermeable films on sidewalls of the semiconductor nanosheets;
removing the semiconductor nanosheets to form a plurality of cavities between the first semiconductor layers;
forming a plurality of sacrificial inner spacers in a plurality of inner spaces defined by the semipermeable films;
forming a separation layer in a trench of the substrate, and the separation layer being connected to a lowermost one of the sacrificial inner spacers; and
forming an epitaxial source/drain feature such that the sides of the epitaxial source/drain feature are in contact with the first semiconductor layers and the sacrificial inner spacers, and the bottom of the epitaxial source/drain feature is in contact with the separation layer.

14. The method of claim 13, wherein a top surface of the separation layer is higher than an upper surface of the substrate, and a connection gap is formed between the bottom of the epitaxial source/drain feature and the trench.

15. The method of claim 14, further comprising:
removing the sacrificial inner spacers and the separation layer to expose the sides and bottom of the epitaxial source/drain feature;
forming a plurality of dielectric spacers on opposite sides of the epitaxial source/drain feature; and
forming a bottom dielectric layer in the trench of the substrate, and the bottom dielectric layer is connected to a lowermost one of dielectric spacers.

16. The method of claim 15, wherein the bottom dielectric layer is a hollow dielectric structure containing air.

17. The method of claim 15, wherein the dielectric spacers are hollow spacers, and the hollow spacers contain air.

18. A semiconductor device, comprising:
a substrate having a trench and an separation layer located in the trench, and a top surface of the separation layer being higher than a top surface of the substrate;
a first epitaxial source/drain feature formed on the separation layer;
a second epitaxial source/drain feature formed on the separation layer;
two or more semiconductor layers electrically connected between the first epitaxial source/drain feature and the second epitaxial source/drain feature; and
a plurality of dielectric spacers located between the two or more semiconductor layers, the dielectric spacers being located between two opposite sides of the first epitaxial source/drain feature and the second epitaxial source/drain feature, wherein a lowermost one of the dielectric spacers is connected to the separation layer.

19. The method of claim 18, wherein the dielectric spacers contain air and the separation layer contains air.

20. The method of claim 18, wherein the dielectric spacers are hollow spacers, and the separation layer is a hollow dielectric structure.
